(19) United States
(12) Patent Application Publication
(10) Pub. No.: US 2018/0019723 A1
(43) Pub. Date: Jan. 18, 2018

(54) BULK ACOUSTIC WAVE FILTER DEVICE

(71) Applicant: SAMSUNG ELECTRO-MECHANICS CO., LTD., Suwon-si (KR)

(72) Inventors: Chang Hyun LIM, Suwon-si (KR); Jae Chang LEE, Suwon-si (KR); Sung Min CHO, Suwon-si (KR); Tae Kyung LEE, Suwon-si (KR); Moon Chul LEE, Suwon-si (KR)

(73) Assignee: SAMSUNG ELECTRO-MECHANICS CO., LTD., Suwon-si (KR)

(21) Appl. No.: 15/623,703

(22) Filed: Jun. 15, 2017

(30) Foreign Application Priority Data
Jul. 14, 2016 (KR) 10-2016-0089378
Nov. 21, 2016 (KR) 10-2016-0154674

(51) Int. Cl. H03H 9/02; H03H 9/56; H01L 41/047

(52) U.S. Cl. CPC H03H 9/02118; H01L 41/0472; H03H 9/564

(57) ABSTRACT

A bulk acoustic wave filter device includes a resonating part, an electrode connecting part, a first layer, and a second layer. The resonating part is disposed on a substrate, and the electrode connecting part connects electrodes of the resonating part. The first layer is disposed on the substrate, and the second layer is disposed on regions of the first layer, other than a lower portion of the electrode connecting part.

### CROSS-REFERENCE TO RELATED APPLICATION(S)

This application claims the benefit under 35 USC 119(a) of Korean Patent Application Nos. 10-2016-0089378, filed on Jul. 14, 2016 and 10-2016-0154674, filed on Nov. 21, 2016 in the Korean Intellectual Property Office, the disclosures of which are incorporated herein by reference in their entirety.

### BACKGROUND

### 1. Field

The following description relates to a bulk acoustic wave filter device.

### 2. Description of Related Art

Currently, in accordance with the rapid development of communications technology, there is a demand for the development of a signal processing technology and a radio frequency (RF) component technology.

In particular, in accordance with a miniaturization trend for a wireless communications device, there is an active demand for a miniaturization of the radio frequency components. Miniaturization of a filter among radio frequency components has been implemented by manufacturing the filter as a bulk acoustic wave (BAW) resonator using a technology that manufactures a semiconductor thin film wafer.

The bulk acoustic wave (BAW) resonator implements a thin film type element where a piezoelectric dielectric material is deposited on a silicon wafer, which is a semiconductor substrate, to produce resonance by using piezoelectric characteristics of the piezoelectric dielectric material as the filter. Application fields of the bulk acoustic wave (BAW) resonator include small and light weight filters such as those used in mobile communications devices, chemical and bio devices, and other similar devices, an oscillator, a resonance element, and an acoustic resonance mass sensor.

Further, various structural shapes and functions to enhance functional and structural characteristics of the bulk acoustic wave resonator have been researched, and there is a need to develop a structure and a technique to reduce variation of the characteristics of the bulk acoustic wave resonator.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a bulk acoustic wave filter device, including: a resonating part disposed on a substrate; an electrode connecting part connecting electrodes of the resonating part; a first layer disposed on the substrate; and a second layer disposed on regions of the first layer, other than a lower portion of the electrode connecting part.

The first layer may be formed of silicon oxide (SiO₂), a material containing silicon oxide (SiO₂), aluminum nitride (AlN), or a material containing aluminum nitride (AlN), and the second layer may be formed of silicon nitride (SiN) or a material containing SiN.

An air gap may be disposed below the first layer, disposed in a lower portion of the resonating part.

The resonating part may include: a lower electrode disposed on the second layer; a piezoelectric layer disposed to cover a portion of the lower electrode; and an upper electrode disposed on the piezoelectric layer.

The bulk acoustic wave filter device may further include: a frame layer disposed on the upper electrode.

The frame layer and the upper electrode may be formed of the same material.

The bulk acoustic wave filter device may further include: a third layer, disposed to cover the frame layer and the upper electrode.

The bulk acoustic wave filter device may further include: a frame layer disposed between the upper electrode and the piezoelectric layer.

In accordance with an embodiment, there is provided a bulk acoustic wave filter device, including: a resonating part disposed on a substrate; an electrode connecting part connecting electrodes of the resonating part; a first layer disposed on the substrate and formed of silicon oxide (SiO₂), a material comprising silicon oxide (SiO₂), aluminum nitride (AlN), or a material comprising aluminum nitride (AlN); and a second layer disposed on the first layer, other than a lower portion of the electrode connecting part, and formed of silicon nitride (SiN) or a material containing silicon nitride (SiN).

The second layer may be disposed on the first layer so as to be disposed on remaining portions of the first layer, except the electrode connecting part.

The second layer may be disposed in a lower portion of the resonating part.

An air gap may be disposed below the first layer disposed in a lower portion of the resonating part.

The resonating part may include: a lower electrode disposed on the second layer; a piezoelectric layer disposed to cover a portion of the lower electrode; and an upper electrode disposed on the piezoelectric layer.

The bulk acoustic wave filter device may further include: a frame layer disposed on the upper electrode.

The upper electrode and the frame layer may be formed of the same material.

The bulk acoustic wave filter device may further include: a third layer disposed to cover the frame layer and the upper electrode.

The bulk acoustic wave filter device may further include: a frame layer disposed between the upper electrode and the piezoelectric layer.

In accordance with an embodiment, there is provided a bulk acoustic wave filter device, including: a first layer disposed on a substrate and including an air gap disposed between the substrate and the first layer; a second layer; a third layer disposed over portions of the first layer; a lower electrode disposed on a portion of the second layer and a portion of the first layer; and a piezoelectric layer covering a portion of the lower electrode and a portion of the second layer, wherein the second layer may be disposed on the first layer, over the air gap, other than a region in which the third layer and the lower electrode may be disposed on the first layer.

The second layer may be disposed on the first layer, other than a region in which the piezoelectric layer may be disposed on the first layer.

The lower electrode disposed from a side surface of the second layer, at which the region in which the piezoelectric layer and the third layer may be disposed, to cover at least a portion of the second layer.

Other features and aspects will be apparent from the following detailed description, the drawings, and the claims.

### BRIEF DESCRIPTION OF DRAWINGS

FIG. 1 is a plan view schematically illustrating a bulk acoustic wave filter device, according to an embodiment;

FIG. 2 is a schematic cross-sectional view illustrating a portion of the bulk acoustic wave filter device, according to an embodiment;

FIGS. 3 through 11 are process views illustrating a method to manufacture a bulk acoustic wave filter device, according to an embodiment; and

FIG. 12 is a schematic cross-sectional view illustrating a bulk acoustic wave filter device, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

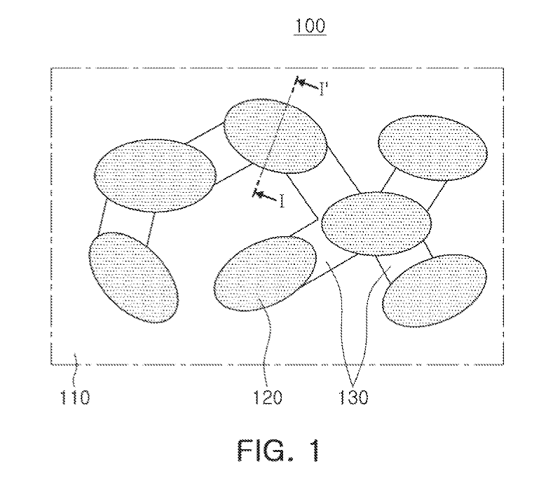

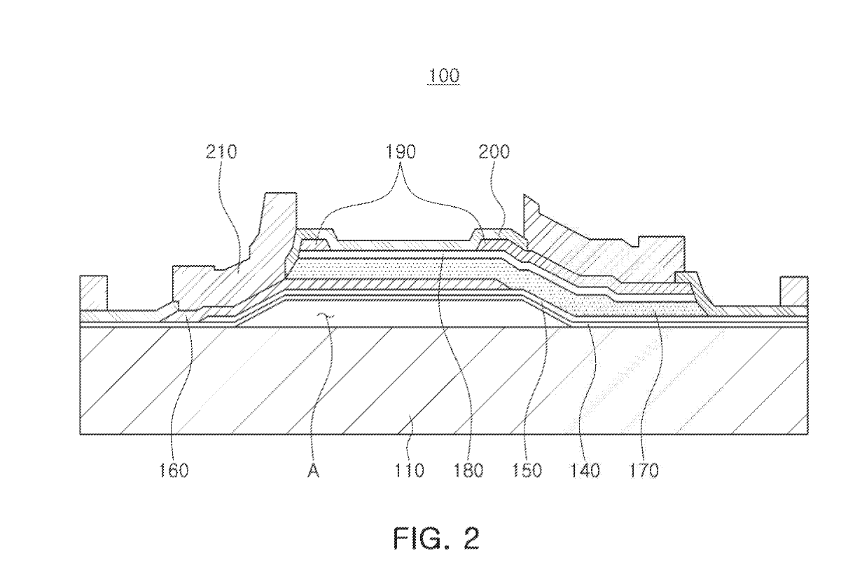

FIG. 1 is a plan view schematically illustrating a bulk acoustic wave filter device, according to an embodiment, and FIG. 2 is a schematic cross-sectional view illustrating a portion of the bulk acoustic wave filter device, according to an embodiment.

Referring to FIGS. 1 and 2, a bulk acoustic wave filter device 100 includes a substrate 110, a plurality of resonating parts 120 formed or disposed on the substrate 110, and electrode connecting parts 130 to electrically connect the resonating parts 120 to each other, by way of example. For purposes of description, the term disposed will be used to describe the formation and disposition of the various layers and elements described in the present description.

That is, the bulk acoustic wave filter device 100 includes the resonating parts 120, which are connected to each other through the electrode connecting parts 130, to implement filter characteristics.

In an example, each resonating part 120 is a configuration of the bulk acoustic wave filter device 100 that deforms together with a piezoelectric layer 170, as the piezoelectric layer 170, to be described below, deforms.

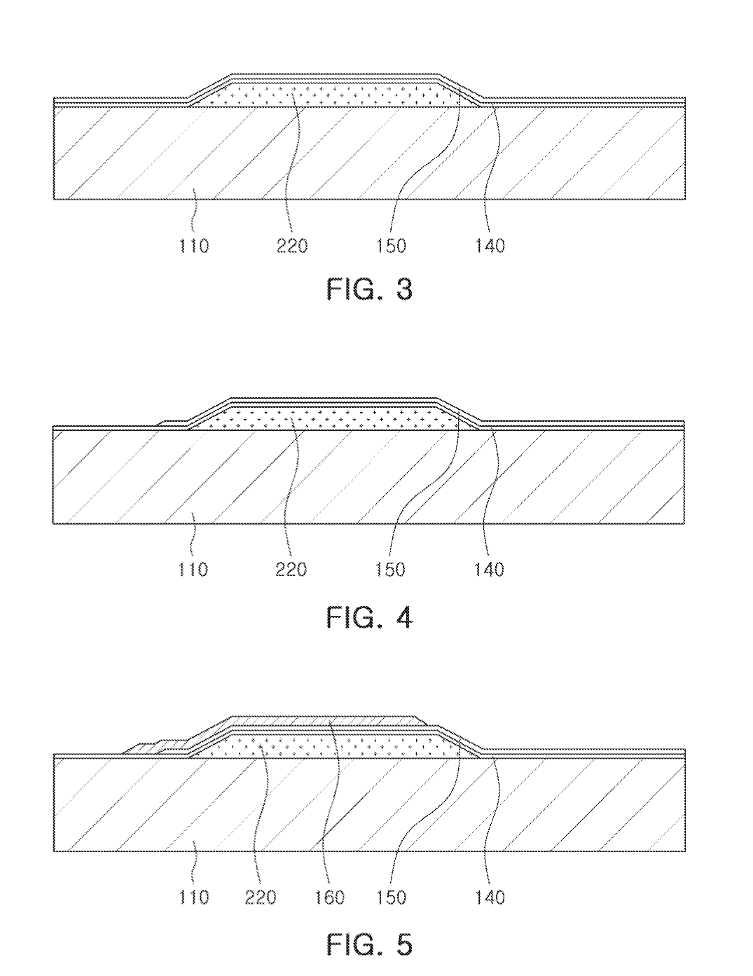

Furthermore, the bulk acoustic wave filter device 100 also includes a first layer 140, by way of example. The first layer 140 is disposed on the substrate 110; over, covering, or encompassing an air gap A, which is defined between the substrate 110 and the first layer 140. That is, the first layer 140 is disposed on the substrate 110 and a sacrificial layer 220 (illustrated and described with respect to FIGS. 3 through 10) so as to cover the sacrificial layer 220 disposed on the substrate 110. Thereafter, in an example in which the sacrificial layer 220 is removed, the air gap A is disposed below the first layer 140.

In one embodiment, the first layer 140 is formed of silicon oxide (SiO₂), a material containing silicon oxide (SiO₂), aluminum nitride (AlN), or a material containing aluminum nitride (AlN). Also, the first layer 140 may also serve to prevent etching of a lower end portion of the resonating part 120 upon an operation of removing the sacrificial layer 220 being performed.

Further, a second layer 150 is disposed on the first layer 140, other than a lower portion of the electrode connecting part 130, and may be formed of silicon nitride (SiN) or a material containing silicon nitride (SiN).

As an example, after the second layer 150 is disposed on an entire region of the first layer 140, the second layer 150 is partially removed from a portion of the first layer 140 on which the electrode connecting part 130 is to be disposed. In one example, the second layer 150 is removed through a patterning operation.

In an embodiment, one of the many advantages of the bulk acoustic filter device 100 includes for the second layer 150 and the first layer 140 to compensate for stress caused by the resonating part 120, and reduce the deformation of the structure of the resonating part 120, for example, a phenomenon in which the first layer 140 and the substrate 110 are bonded in the region in which the air gap A is disposed, or a distortion phenomenon between the resonating part 120 and an adjacent region of the resonating part 120.

Further, because the second layer 150 is disposed on the regions of the first layer 140, other than the lower portion of the electrode connecting part 130, as described above, the second layer 150 is configured to reduce an occurrence of a stress imbalance in an outer region of the resonating part 120 to, thus, prevent the distortion phenomenon of the resonating part 120.

The substrate 110 is a substrate on which silicon is stacked. For example, a silicon wafer is used as the substrate. Further, a protection layer (not shown) for protecting silicon may be disposed on a top surface of the substrate 110. That is, the protection layer may be disposed on the top surface of the substrate 110 to prevent etching of the substrate 110 when the operation of removing the sacrificial layer 220 described above is performed.

Also, the resonating part 120 includes a lower electrode 160, a piezoelectric layer 170, an upper electrode 180, a frame layer 190, a third layer 200, and a metal pad 210, as illustrated in FIG. 2.

The lower electrode 160 is disposed on the second layer 150 and a portion of the first layer 140, covering a portion of the second layer 150 or covering the entire second layer 150. As an example, the lower electrode 160 may be formed of a conductive material such as molybdenum (Mo), ruthenium (Ru), tungsten (W), iridium (Ir), platinum (Pt), and the like, or an alloy thereof.

In addition, the lower electrode 160 may be used as either an input electrode that receives an electrical signal such as a radio frequency (RF) signal, or may be used as an output electrode. In an example in which the lower electrode 160 is the input electrode, the upper electrode 180 is the output electrode. In another example in which the lower electrode 160 is the output electrode, the upper electrode 180 is the input electrode and receives the electrical signal.

In one configuration, the piezoelectric layer 170 covers at least a portion of the lower electrode 160 and a portion of the second layer 150. In addition, the piezoelectric layer 170 converts the electric signal input from the lower electrode 160 or the upper electrode 180 into an acoustic wave.

As an example, in response to an electric field that changes over time is maintained in the upper electrode 180, the piezoelectric layer 170 converts the electric signal input from the upper electrode 180 into physical vibration. In addition, the piezoelectric layer 170 converts the converted physical vibration into an acoustic wave. In this case, the electric field that changes over time may be induced. As a result, the piezoelectric layer 170 generates a bulk acoustic wave in the same direction as a thickness vibration direction within the piezoelectric layer 170 oriented using the induced electric field.

As such, the piezoelectric layer 170 generates the bulk acoustic wave to convert the electric signal into the acoustic wave.

In this example, the piezoelectric layer 170 is formed by depositing aluminum nitride, zinc oxide, or lead zironate titanate on the lower electrode 160. When the piezoelectric layer 150 is made of aluminum nitride (AlN), the piezoelectric layer 150 may further include a rare earth metal. For example, the rare earth metal may include at least one of scandium (Sc), erbium (Er), yttrium (Y), and lanthanum (La).

The upper electrode 180 is formed on the piezoelectric layer 170, and is formed of a conductive material such as molybdenum (Mo), ruthenium (Ru), tungsten (W), iridium (Ir), platinum (Pt), and the like, or an alloy thereof, by way of example. In addition, the upper electrode 180 may be used as either an input electrode that receives an electric signal such as a radio frequency (RF) signal, or an output electrode that outputs the RF signal, as described above.

The frame layer 190 is disposed on the upper electrode 180. As an example, the frame layer 190 is disposed on the upper electrode 180 and is disposed on the upper electrode 180, other than a central portion of the resonating part 120. Further, the frame layer 190 may be disposed of the same material as the upper electrode 180. However, the material of the frame layer 190 is not limited thereto, and the frame layer 190 may be formed of a material different from the upper electrode 180.

The frame layer 190 reflects a lateral wave generated at a time of resonating into an active region, to confine resonant energy in the active region.

According to an embodiment, the frame layer 190 is disposed on the upper electrode 180. However, in an alternative embodiment, the frame layer 190 may be disposed on the piezoelectric layer 170, while the upper electrode 180 may also be disposed to cover the frame layer 190.

As shown in FIG. 2, the third layer 200 is disposed over the first layer 140, covering at least a side portion of the lower electrode 160, at least a side portion of the piezoelectric layer 170, at least a side portion of the upper electrode 180, an entire side portion of the frame layer 190, and at least a portion of another side of the frame layer 190. The third layer 200 prevents the frame layer 190 and the upper electrode 180 from being damaged during an operation. Further, a thickness of the third layer 200 may vary based on a particular application and may be adjusted by etching to adjust a frequency.

In addition, although not shown in detail in the drawings, the third layer 200 may also be disposed on all other regions of the substrate 110, for example, covering at least a portion of the second layer 150, other than the region on which the metal pad 210 is disposed.

The metal pad 210 is electrically connected to the lower electrode 160 and the upper electrode 180.

As described above, the second layer 150, together with the first layer 140, compensate for stress caused by the resonating part 120, and reduce the deformation of the structure of the resonating part 120, in a phenomenon, for example, in which the first layer 140 and the substrate 110 are bonded in the region in which the air gap A is disposed, or in a distortion phenomenon between the resonating part 120 and an adjacent region of the resonating part 120.

Further, because the second layer 150 is disposed on all regions except the lower portion of the electrode connecting part 130, as described above, the second layer 150 may prevent the distortion phenomenon of the resonating part 120 due to a stress imbalance at an outer region of the resonating part 120.

In other words, as compared to a configuration in which the second layer 150 is disposed only on the lower portion of the resonating part 120, the distortion phenomenon of the resonating part 120 due to the stress imbalance in the outer region of the resonating part 120 may be prevented.

In addition, insertion loss may be reduced by removing the second layer 150 from the electrode connecting part 130.

In other words, leakage characteristics in the electrode connecting part 130 are improved, to contribute to the improvement of characteristics (IL characteristics) of an entire filter device, and an occurrence of abnormal stiction due to stress variation is controlled by applying a composite thin film including the first layer 140 and the second layer 150 to all regions, except the electrode connecting part 130.

As a result, leakage characteristics are improved and a stable structure in the resonating part 120 is implemented.

Hereinafter, a method to manufacture a bulk acoustic wave filter device, according to an embodiment, will be described with reference to the drawings.

FIGS. 3 through 11 are process views illustrating a method to manufacture a bulk acoustic wave filter device, according to an embodiment.

As illustrated in FIG. 3, the sacrificial layer 220, the first layer 140, and the second layer 150 are sequentially formed on the substrate 110. The first layer 140 may be formed of silicon oxide (SiO₂), a material containing silicon oxide (SiO₂), aluminum nitride (AlN), or a material containing aluminum nitride (AlN), and the second layer 150 may be silicon nitride (SiN) or a material containing silicon nitride (SiN).

Next, as illustrated in FIG. 4, a portion of the second layer 150 is removed by a patterning operation. In the patterning operation, the second layer 150 is removed from the region on which the electrode connecting part 130 is to be disposed.

In other words, a portion of the second layer 150 is removed using the patterning operation so that the second layer 150 is present in an outer region of the resonating part 120, other than the region on which the resonating part 120 (FIG. 1) and the electrode connecting part 130 are disposed.

That is, a composite thin film including the first layer 140 and the second layer 150 is applied to all regions of the substrate 110 and the sacrificial layer 220, except the electrode connecting part 130.

Next, as illustrated in FIG. 5, the lower electrode 160 is disposed. The lower electrode 160 is disposed on the second layer 150. The lower electrode 160 is formed of a conductive material such as molybdenum (Mo), ruthenium (Ru), tungsten (W), iridium (Ir), platinum (Pt), and the like, or an alloy thereof.

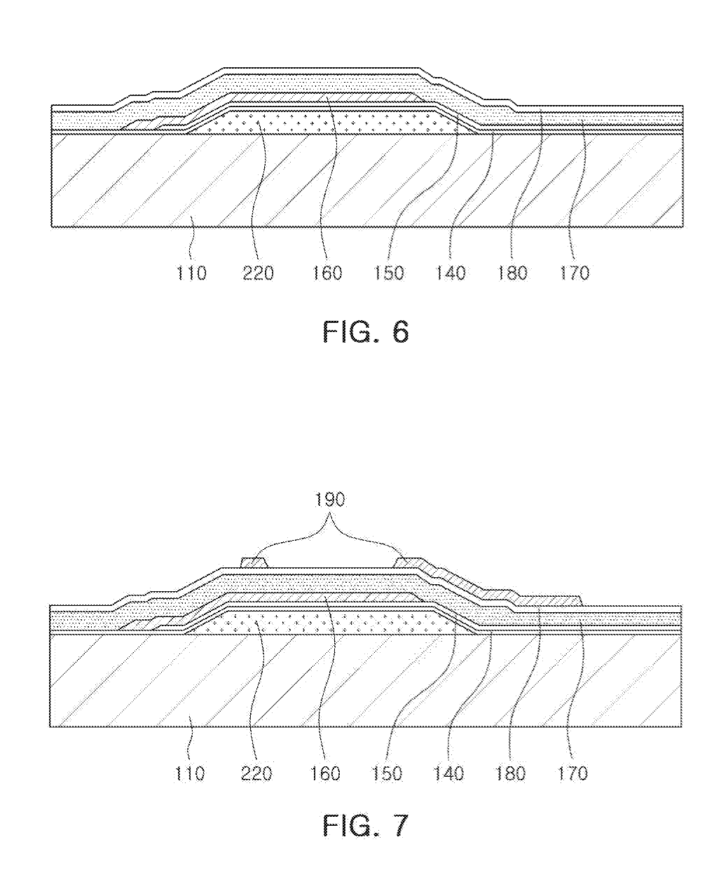

Next, as illustrated in FIG. 6, the piezoelectric layer 170 and the upper electrode 180 are sequentially disposed. Further, the piezoelectric layer 170 is formed by depositing aluminum nitride, zinc oxide, or lead zirconate titanate, and the upper electrode 180 is formed of a conductive material such as molybdenum (Mo), ruthenium (Ru), tungsten (W), iridium (Ir), platinum (Pt), and the like, or an alloy thereof, which is the same material as the lower electrode 160 described above.

In addition, as illustrated in FIG. 7, the frame layer 190 is disposed on the upper electrode 180.

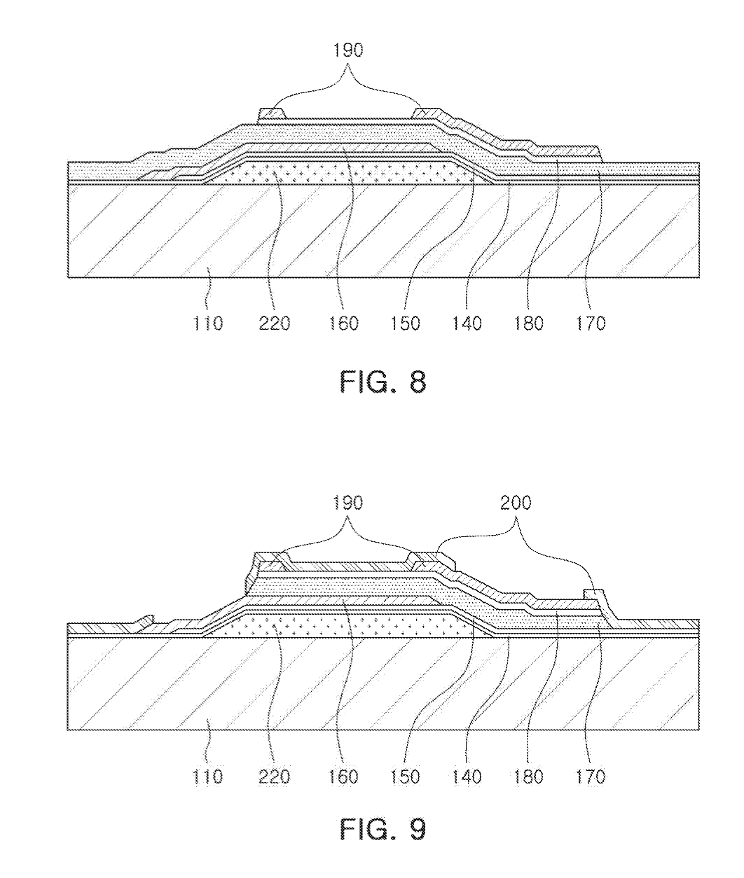

Portions of the upper electrode 180 and of the frame layer 190 may be removed by a patterning operation, as illustrated in FIG. 8.

Next, as illustrated in FIG. 9, after a portion of the piezoelectric layer 170 is removed by the patterning operation, the third layer 200 is formed. Subsequently, a portion of the third layer 200 is removed by the patterning operation.

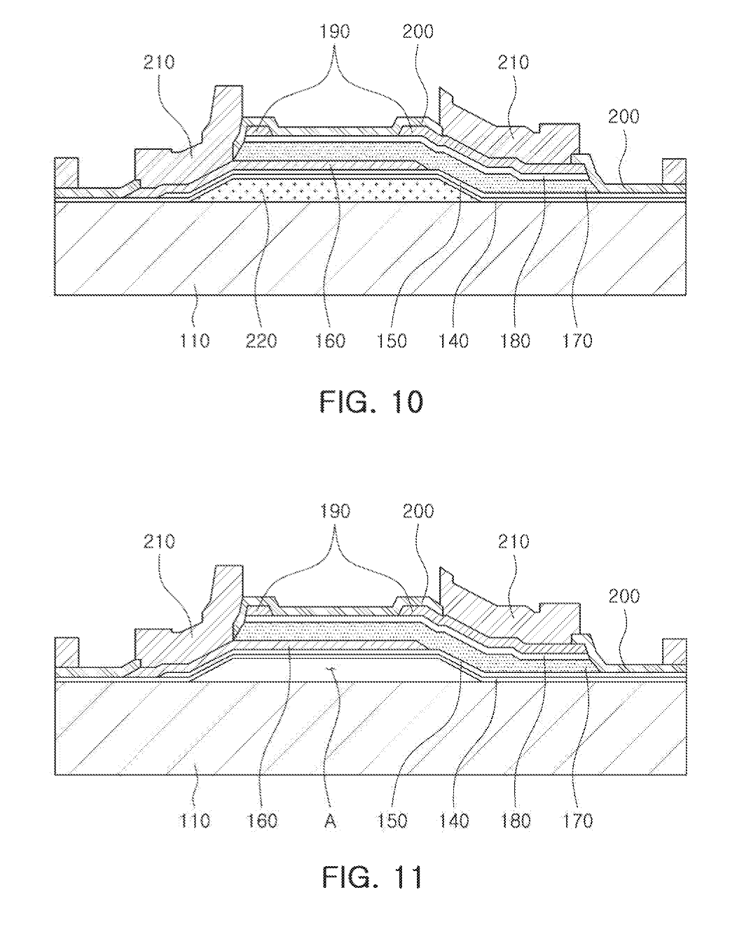

As illustrated in FIG. 10, the metal pad 210 is disposed on the portions of the lower electrode 140 and the frame layer 190 exposed by a removal of the third layer 200.

Then, as illustrated in FIG. 11, the sacrificial layer 220 is removed to form the air gap A.

As described above, the second layer 150, disposed on the region on which the electrode connecting part 130 is disposed after the second layer 150 is disposed, and is removed by the patterning operation.

As such, the bulk acoustic wave filter device 100, which improves leakage characteristics and implement a stable structure in the resonating part 120 without adding a complex operation by adding the patterning operation of the second layer 150, is manufactured.

Hereinafter, a bulk acoustic wave filter device, according to another embodiment, will be described with reference to the drawings. In these drawings, the same components as the above-mentioned components will be denoted by the same reference numerals used above, and a detailed description thereof will be omitted.

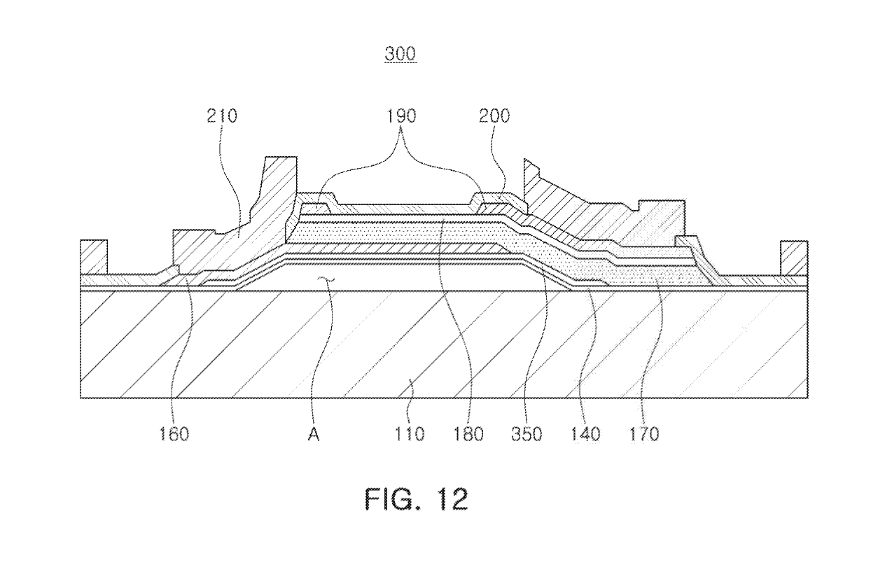

FIG. 12 is a schematic cross-sectional view illustrating a bulk acoustic wave filter device, according to another embodiment.

Referring to FIGS. 1 and 12, a bulk acoustic wave filter device 300, according to an embodiment, includes a substrate 110, a plurality of resonating parts 120 disposed on the substrate 110, and electrode connecting parts 130, to electrically connect the resonating parts 120 to each other.

That is, the bulk acoustic wave filter device 300 includes the plurality of resonating parts 120, and the respective resonating parts 120 are connected to each other through the electrode connecting part 130 to implement improved filter characteristics.

Meanwhile, the bulk acoustic wave filter device 300 further includes a first layer 140. The first layer 140 is disposed on the substrate 110 and covering an air gap A. That is, the first layer 140 is disposed on the substrate 110 and a sacrificial layer 220 (to be later removed, leaving the air gap A between the substrate 110 and the first layer 140) so as to cover the sacrificial layer 220, to be described below, disposed on the substrate 110. Thereafter, in a case in which the sacrificial layer 220 is removed, the air gap A is disposed between the substrate 110 and the first layer 140.

As an example, the first layer 140 is formed of silicon oxide (SiO₂), a material containing silicon oxide (SiO₂), aluminum nitride (AlN), or a material containing aluminum nitride (AlN). Also, the first layer 140 serves to prevent etching of a lower end portion of the resonating part 120 upon an operation of removing the sacrificial layer 220 being performed.

Further, a second layer 350 is disposed on the first layer 140, and is disposed in a lower region of the resonating part 120. The second layer 350 is not disposed in an outer region of the resonating part 120, that is, in the remaining regions of the substrate 110, other than the portions on which the electrode connecting part 130 and the resonating part 120 are disposed. The second layer 350 may be formed of silicon nitride (SiN) or a material containing silicon nitride (SiN).

As an example, after the second layer 350 is disposed on an entire region of the first layer 140, the second layer 350 is then removed from a region in which the piezoelectric layer 170 and the third layer 200 are to be disposed. The second layer 350 remains on the region on which the resonating part 120 is to be disposed. In this case, the second layer 350 may be removed using a patterning operation.

As described above, because the second layer 350 is disposed only in the resonating part 120, an occurrence of an abnormal shape due to stress variation may be prevented, and insertion loss is reduced by removing the second layer 350 from the electrode connecting part 130.

In other words, leakage characteristics in the electrode connecting part 130 are improved to contribute to the improvement of characteristics (IL characteristics) of an entire filter device. Also, an occurrence of an abnormal stiction due to stress variation is controlled by applying a composite thin film, including the first layer 140 and the second layer 350, to the region of the resonating part 120.

As a result, leakage characteristics are improved and a stable structure in the resonating part 120 may be implemented.

As set forth above, according to an embodiment, the insertion loss may be reduced.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave filter device, comprising:
a resonating part disposed on a substrate;
an electrode connecting part connecting electrodes of the resonating part;
a first layer disposed on the substrate; and
a second layer disposed on regions of the first layer, other than a lower portion of the electrode connecting part.

2. The bulk acoustic wave filter device of claim 1, wherein the first layer is formed of silicon oxide (SiO₂), a material containing silicon oxide (SiO₂), aluminum nitride (AlN), or a material containing aluminum nitride (AlN), and the second layer is formed of silicon nitride (SiN) or a material containing SiN.

3. The bulk acoustic wave filter device of claim 1, wherein an air gap is disposed below the first layer, disposed in a lower portion of the resonating part.

4. The bulk acoustic wave filter device of claim 1, wherein the resonating part comprises:
a lower electrode disposed on the second layer;
a piezoelectric layer disposed to cover a portion of the lower electrode; and
an upper electrode disposed on the piezoelectric layer.

5. The bulk acoustic wave filter device of claim 4, further comprising:
a frame layer disposed on the upper electrode.

6. The bulk acoustic wave filter device of claim 5, wherein the frame layer and the upper electrode are formed of the same material.

7. The bulk acoustic wave filter device of claim 5, further comprising:
a third layer, disposed to cover the frame layer and the upper electrode.

8. The bulk acoustic wave filter device of claim 5, further comprising:
a frame layer disposed between the upper electrode and the piezoelectric layer.

9. A bulk acoustic wave filter device, comprising:
a resonating part disposed on a substrate;
an electrode connecting part connecting electrodes of the resonating part;
a first layer disposed on the substrate and formed of silicon oxide (SiO₂), a material comprising silicon oxide (SiO₂), aluminum nitride (AlN), or a material comprising aluminum nitride (AlN); and
a second layer disposed on the first layer, other than a lower portion of the electrode connecting part, and formed of silicon nitride (SiN) or a material containing silicon nitride (SiN).

10. The bulk acoustic wave filter device of claim 9, wherein the second layer is disposed on the first layer so as to be disposed on remaining portions of the first layer, except the electrode connecting part.

11. The bulk acoustic wave filter device of claim 9, wherein the second layer is disposed in a lower portion of the resonating part.

12. The bulk acoustic wave filter device of claim 9, wherein an air gap is disposed below the first layer disposed in a lower portion of the resonating part.

13. The bulk acoustic wave filter device of claim 12, wherein the resonating part comprises:
a lower electrode disposed on the second layer;
a piezoelectric layer disposed to cover a portion of the lower electrode; and
an upper electrode disposed on the piezoelectric layer.

14. The bulk acoustic wave filter device of claim 13, further comprising:
a frame layer disposed on the upper electrode.

15. The bulk acoustic wave filter device of claim 14, wherein the upper electrode and the frame layer are formed of the same material.

16. The bulk acoustic wave filter device of claim 14, further comprising:
a third layer disposed to cover the frame layer and the upper electrode.

17. The bulk acoustic wave filter device of claim 14, further comprising:
a frame layer disposed between the upper electrode and the piezoelectric layer.

18. A bulk acoustic wave filter device, comprising:
a first layer disposed on a substrate and including an air gap disposed between the substrate and the first layer;
a second layer;
a third layer disposed over portions of the first layer;
a lower electrode disposed on a portion of the second layer and a portion of the first layer; and
a piezoelectric layer covering a portion of the lower electrode and a portion of the second layer,
wherein the second layer is disposed on the first layer, over the air gap, other than a region in which the third layer and the lower electrode are disposed on the first layer.

19. The bulk acoustic wave filter device of claim 18, wherein the second layer is disposed on the first layer, other than a region in which the piezoelectric layer is disposed on the first layer.

20. The bulk acoustic wave filter device of claim 18, wherein the lower electrode disposed from a side surface of the second layer, at which the region in which the piezoelectric layer and the third layer are disposed, covers at least a portion of the second layer.
